(19) United States
(12) Patent Application Publication
(10) Pub. No.: US 2006/0043578 A1
(43) Pub. Date: Mar. 2, 2006

(54) Semiconductor device having heat sink

(76) Inventors: Hyo-Jae Bang, Cheonan-si (KR); Byung-Man Kim, Cheonan-si (KR); Dong-Chun Lee, Cheonan-si (KR); Kwang-Su Yu, Cheonan-si (KR)

Correspondence Address: HARNESS, DICKEY & PIERCE, P.L.C., P.O. BOX 8910, RESTON, VA, 20195, US

(21) Appl. No.: 11/038,211

(22) Filed: Jan. 21, 2005

(30) Foreign Application Priority Data
Aug. 24, 2004 (KR) 2004-66819

(51) Int. Cl. H01L 23/34

(52) U.S. Cl. 257/706

(57) ABSTRACT

A semiconductor device, which may include a heat sink using a thermal induced adhesive is provided. The adhesive strength of the thermal induced adhesive at room temperature may be reduced when heated. The thermal induced adhesive may attach the heat sink to the semiconductor device, and may result in a thinner semiconductor device.

### CROSS REFERENCE TO RELATED APPLICATIONS

This U.S. non-provisional application claims benefit of priority under 35 U.S.C. §119 of Korean Patent Application No. 2004-66819, filed on Aug. 24, 2004, the entire contents of which are incorporated herein by reference.

### BACKGROUND OF THE INVENTION

1. Field of the Invention

Example embodiments of the present invention relate to semiconductor devices.

2. Description of the Conventional Art

A stack package may have a plurality of semiconductor chips and/or a plurality of semiconductor packages, and a semiconductor module may have a plurality of semiconductor packages and/or a plurality of stack packages.

Semiconductor devices, for example, stack packages and/or semiconductor modules may generate heat during operation and a heat sink may be provided to radiate the heat.

A stack package 10 illustrated in FIG. 1 may have a plurality of semiconductor packages 12, 14, 16 and 18. A heat sink 20 may be attached to the uppermost semiconductor package 18, for example, via a thermosetting adhesive 30.

A process, for example, a test process may include a visual inspection, which may be performed on the stack package 10. The stack package 10 may be determined to be faulty and may be repaired. In another process, for example, a repair process, the heat sink 20 may be separated from the stack package 10.

The thermosetting adhesive 30 interposed between the heat sink 20 and the stack package 10 may make separating the heat sink 20 from the stack package 10 more difficult, and may change the stack package 10.

A similar problem may occur in connection with a semiconductor module.

A semiconductor module 40 as illustrated in FIGS. 2 and 3 may have heat sinks 50, which may use thermal transfer intermediate materials 60. The semiconductor module 40 may have a board 42 (e.g., a printed circuit board (PCB) or flexible PCB), and a plurality of semiconductor packages 44 mounted on one or both sides of the board 42. The heat sinks 50 may be attached to the semiconductor packages 44 using, for example, the thermal transfer intermediate materials 60.

The thermal transfer intermediate material 60 may have lower adhesive strength than the thermosetting adhesive 30 depicted in FIG. 1. The heat sink 50 may be fixed to the semiconductor module 40, for example, via a clip 70 or a bolt and nut, which may be added to, or used in conjunction with, the thermal transfer intermediate material 60.

The clip 70 may be formed of, for example, a clamp and/or a bracket. The semiconductor module 40 may be fastened with, for example, the clip 70, which may result in the heat sink 50 being fixed to the semiconductor module 40.

### SUMMARY OF THE INVENTION

An example embodiment of the present invention may be directed to a semiconductor device, in which a heat sink may be attached to the semiconductor device, for example, via an adhesive (e.g., a thermal induced adhesive).

Another example embodiment of the present invention may be directed to an adhesive for attaching a component to at least one side of the semiconductor device. The adhesive strength of the adhesive may decrease as the temperature of the adhesive increases.

In another example embodiment of the present invention, a semiconductor device may include a semiconductor module, which may have a board (e.g., a printed circuit board (PCB) or flexible PCB) and at least one semiconductor package, which may be mounted on at least one side of the board. A heat sink may be attached to a surface of the semiconductor package, and the semiconductor package may include a semiconductor package, which may include a single semiconductor chip, a chip stack package, or a package stack package.

In another example embodiment of the present invention, a heat sink may be adhered to at least one side of a semiconductor device using an adhesive. The adhesive may have an adhesive strength, which may decrease when heated.

In another example embodiment of the present invention, a heat sink may be separated from at least one side of a semiconductor device, which may be attached via an adhesive. The heat sink, the adhesive, and the semiconductor device may be heated, and the heat sink and the semiconductor device may be separated such that little or no residue remains on the semiconductor device.

In example embodiments of the present invention, the adhesive may include thermal conductive particles, and the thermal conductive particle may be selected from a group including of metal particles, such as Ag, Cu or Ni, and ceramic particles.

In example embodiments of the present invention, the adhesive may have an adhesive strength, for example, at room temperature, which may be reduced and/or lost when heated.

In example embodiments of the present invention, the semiconductor device may include a semiconductor package, which may include a single semiconductor chip, and/or a stack package including a chip stack package and a package stack package.

In example embodiments of the present invention, a heat sink may be attached to the uppermost semiconductor package or chip of the stack.

### BRIEF DESCRIPTION OF THE DRAWINGS

Example embodiments of the present invention will be readily understood with reference to the following detailed description thereof provided in conjunction with the accompanying drawings, wherein like reference numerals designate like structural elements.

FIG. 1 is a cross-sectional view of a conventional stack package having a heat sink using a thermosetting adhesive.

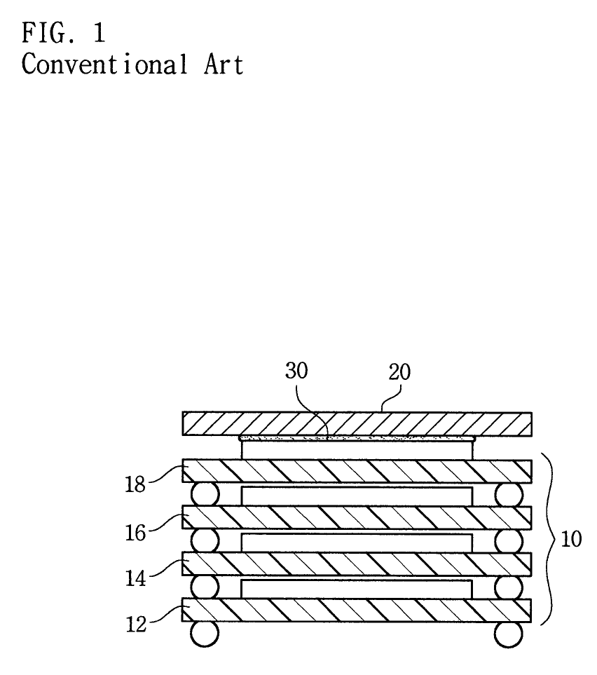

FIG. 2 is an exploded perspective view of a conventional semiconductor module having a heat sink using a thermal transfer intermediate material.

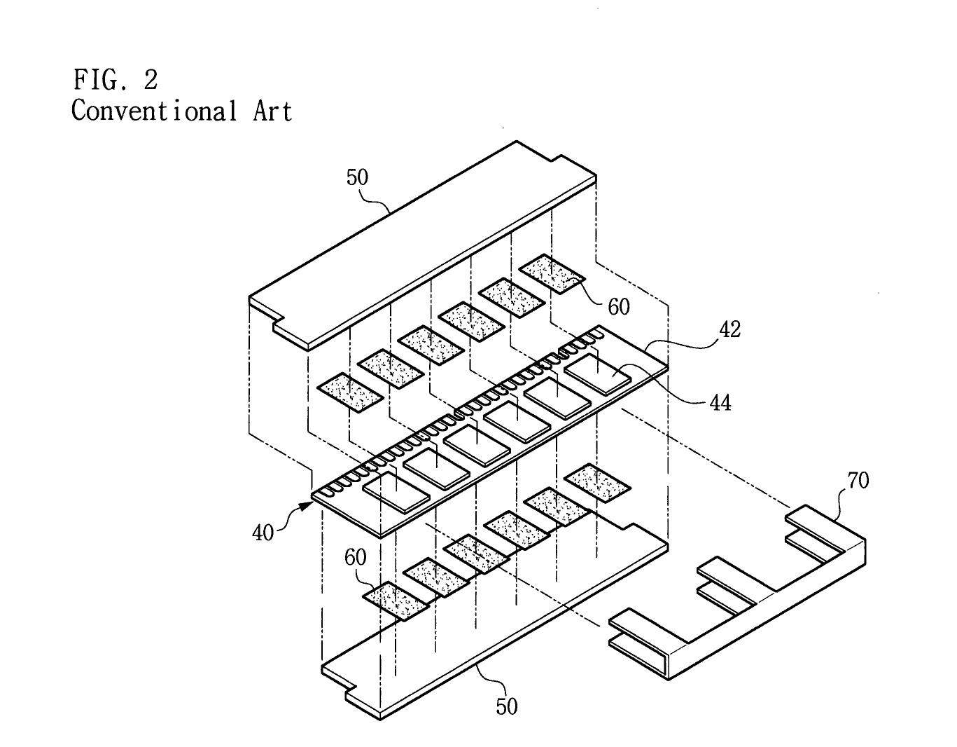

FIG. 3 is a cross-sectional view of the conventional semiconductor module of FIG. 2.

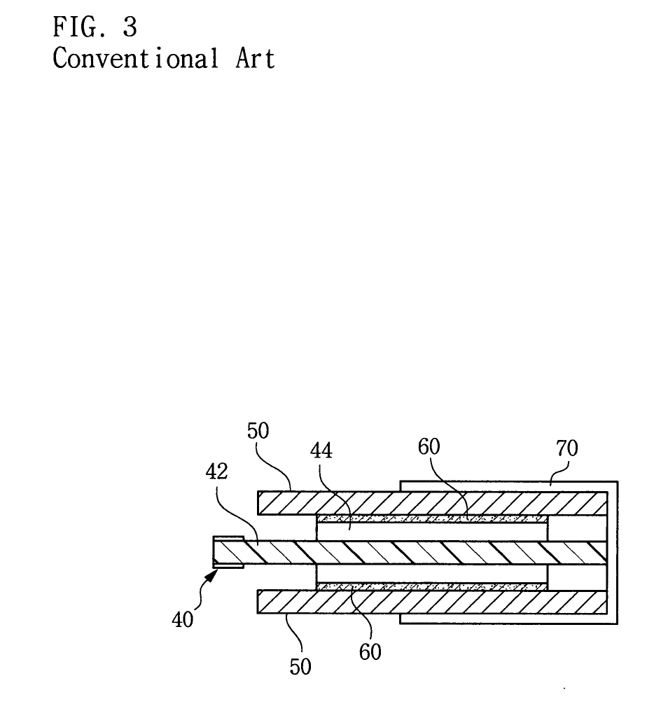

FIG. 4 is a cross-sectional view of a stack package, which may have a heat sink using a thermal induced adhesive according to an example embodiment of the present invention.

FIG. 5 is an exploded perspective view of a semiconductor module, which may have a heat sink using a thermal induced adhesive according to another, non-limiting exemplary embodiment of the present invention.

FIG. 6 is a cross-sectional view of the example embodiments of the semiconductor module of FIG. 5.

These drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the exemplary embodiments of the invention.

### DETAILED DESCRIPTION OF THE EXAMPLE EMBODIMENTS OF THE PRESENT INVENTION

Example embodiments of the present invention will now be described more fully with reference to the accompanying drawings, in which example embodiments of the present invention are illustrated. It will be appreciated that the example embodiments of the present invention may be embodied in many different forms and should not be construed as limited to the example embodiments set forth herein. Rather, the disclosed example embodiments are provided such that this disclosure will be thorough and complete, and will fully convey the scope of the present invention to those skilled in the art.

Well-known structures and processes have not been described or illustrated in detail to avoid obscuring the example embodiments of the present invention. It will be appreciated that for simplicity and clarity of illustration, some elements illustrated in the figures may not be drawn to scale. For example, the dimensions of some of the elements may be exaggerated or reduced relative to other elements for clarity.

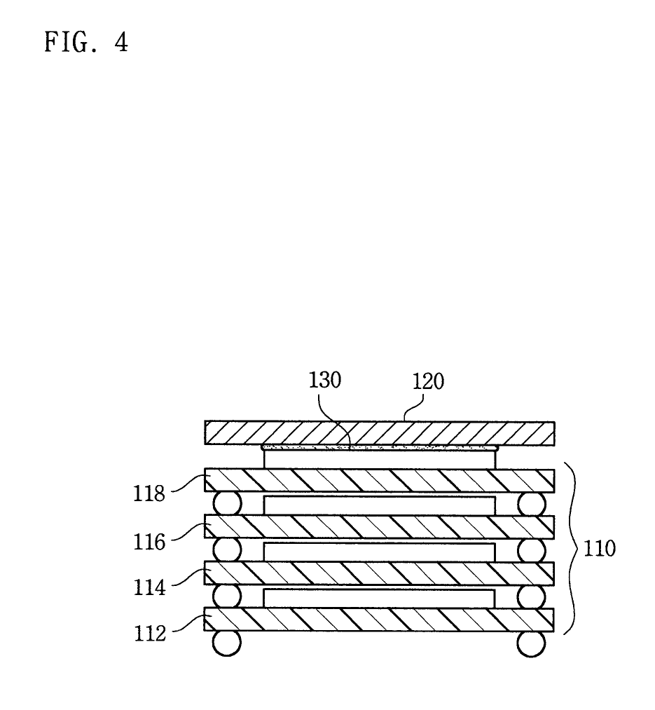

FIG. 4 is a cross-sectional view of a stack package 110, which may have a heat sink 120 using a thermal induced adhesive 130 according to an example embodiment of the present invention.

Referring to FIG. 4, the stack package 110 may have a plurality of semiconductor packages 112, 114, 116 and 118. A heat sink 120 may be attached to a (e.g., the top) surface of the uppermost semiconductor package 118. An adhesive (e.g., thermal induced adhesive) 130 may be interposed between the heat sink 120 and the semiconductor package 118.

The adhesive (e.g., thermal induced adhesive) 130 may include thermal conductive particles. The thermal conductive particles may transfer heat generated by the stack package 110 to the heat sink 120. The adhesive (e.g., thermal induced adhesive) 130 may be provided as liquid type, a film type, or any combination thereof. For example, the thermal induced adhesive 130 may contain, for example, metal particles, such as Ag, Cu or Ni, any alloy thereof, and/or ceramic particles.

The adhesive (e.g., thermal induced adhesive) 130 may have a greater adhesive strength at, for example, room temperature. The adhesive strength of the thermal induced adhesive 130 may be reduced as the temperature rises. For example, during a repair process, the adhesive (e.g., thermal induced adhesive) 130 may facilitate the separation of the heat sink 120 and the stack package 110.

The heat sink 120 may be attached to the stack package 110, for example, using the adhesive at, for example, room temperature. The heat sink 120 should be separated from the stack package 110. Heat may be applied to the stack package 110 and the heat sink may be separated from the stack package 110. The adhesive strength of the adhesive 130 may be reduced, and the heat sink 120 may be more easily separated from the stack package 110.

A new thermal induced adhesive may be used in attaching the heat sink 120 to the stack package 110, for example, after performing the repair process.

Although example embodiments of the present invention are illustrated with respect to the stack package 110 having a plurality of semiconductor packages, a chip stack package, which may have at least one semiconductor chip may be used.

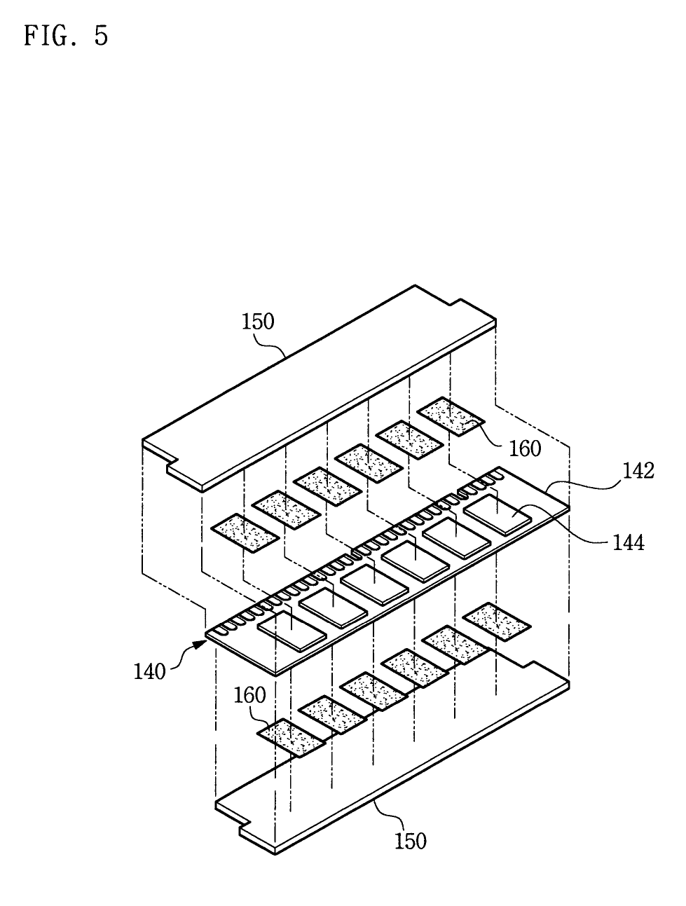

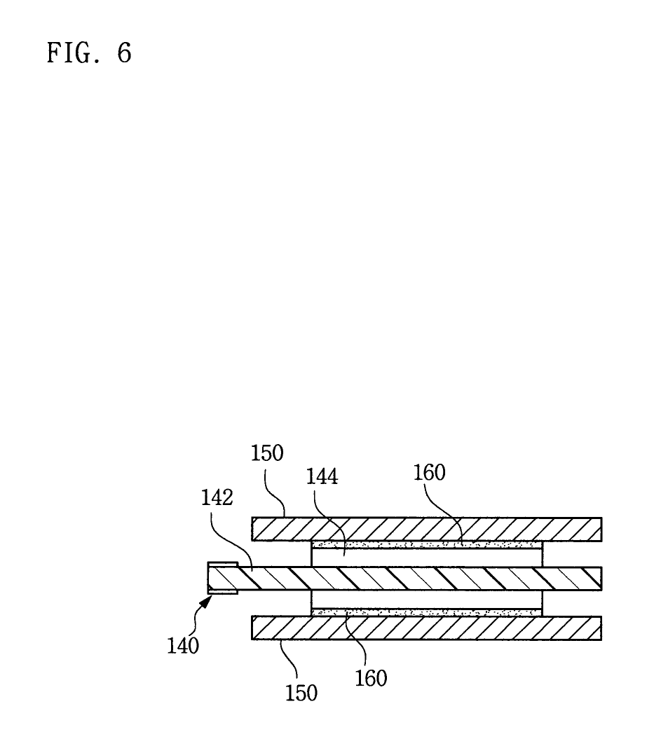

FIG. 5 is an exploded perspective view of a semiconductor module, which may have a heat sink, which may have an adhesive (e.g., a thermal induced adhesive) in accordance with a second example embodiment of the present invention. FIG. 6 is a cross-sectional view of the example embodiment of the semiconductor module of FIG. 5.

Referring to FIGS. 5 and 6, the semiconductor module 140 may have a board 142 and a plurality of semiconductor packages 144 mounted on or both sides of the board 142. Heat sinks 150 may be attached to the semiconductor packages 144 using the adhesives (e.g., thermal induced adhesives) 160.

The adhesive (e.g., thermal induced adhesive) 160 may attach the heat sink 150 to the semiconductor module 140. The adhesive (e.g., thermal induced adhesive) 160 may result in a thinner semiconductor module.

The adhesive strength of the adhesive (e.g., thermal induced adhesive) 160 may be reduced when heated, and the adhesive (e.g., thermal induced adhesive) 160 may facilitate separation of the heat sink 150 from the semiconductor module 140.

The heat sink 150 may be separated from the semiconductor module 140, all, or substantially all, of the adhesive (thermal induced adhesive 160) may be removed from the heat sink 150 and/or the semiconductor module 140, and the likelihood of contamination of the heat sink 150 and/or the semiconductor package 140 may be reduced.

A new adhesive (e.g., thermal induced adhesive) may be used in attaching the heat sink 150 to the semiconductor module 140, for example, after a repair process.

Although example embodiments of the present invention show the semiconductor module 140 having the semiconductor packages 144 mounted on both sides of the board 142, the semiconductor module may have a semiconductor package mounted on one side of the board. The semiconductor package may include a semiconductor package, which may include, for example, a single semiconductor chip, a chip stack package, or a package stack package.

A semiconductor device, which may have a heat sink in accordance with example embodiments of the present invention may have a heat sink, which may use an adhesive (e.g., thermal induced adhesive). The adhesive (e.g., thermal induced adhesive) may attach the heat sink to the semiconductor device and allow for easier separation of the heat sink from the semiconductor device, which may reduce maintenance and/or repair time associated with the semiconductor device, and/or provide simpler repair process.

The heat sink may be separated from the semiconductor device, the adhesive (e.g., thermal induced adhesive) may be removed from the heat sink and/or the semiconductor device, and the likelihood of contamination of the heat sink and/or semiconductor device may be reduced.

Example embodiments of the present invention may reduce the need of the thickness of a semiconductor device.

Although example embodiments have been described with regard to semiconductor devices, packages, and/or modules, it will be understood that example embodiments of the present invention may be used in, or used by, any suitable device, module, package and/or apparatus.

Although example embodiments of the present invention have been described with regard to an adhesive including metal particles, such as Ag, Cu or Ni, and ceramic particles, it will be understood that the adhesive may include any suitable metallic and/or ceramic particles.

Although example embodiments of the present invention are described with regard to an adhesive used to attach a heat sink to, for example, a semiconductor package, it will be understood that the adhesive (e.g., thermal induce adhesive) may be used to attach any suitable component to any suitable semiconductor apparatus. Further, the adhesive may also be used to attach a heat sink to any suitable apparatus.

Although example embodiments of the present invention have been described with regard to semiconductor chips and packages, it will be understood that example embodiments of the present invention may be used in connection with any suitable semiconductor chip, package, device, or combination thereof.

Although example embodiments of the present invention have been described in detail hereinabove, it should be understood that many variations and/or modifications, which may be obvious to those skilled in the art, fall within the spirit and scope of the example embodiments of the present invention as defined in the appended claims.

1. A semiconductor device comprising:
a heat sink provided on at least one side of the semiconductor device; and
an adhesive attaching the heat sink to at least one side of the semiconductor device, wherein
adhesive strength of the adhesive decreases as the temperature of the adhesive increases.

2. The semiconductor device of claim 1, wherein the adhesive includes conductive particles, wherein the conductive particles include at least one of Ag, Cu or Ni, and ceramic particles.

3. The semiconductor device of claim 1, wherein the semiconductor device includes a semiconductor package including at least one semiconductor chip.

4. The semiconductor device of claim 1, wherein the semiconductor device includes a stack package including a plurality of semiconductor packages.

5. The semiconductor device of claim 4, wherein the heat sink is attached to an uppermost semiconductor package of the stack package.

6. The semiconductor device of claim 1, wherein the semiconductor device includes a semiconductor module having at least one semiconductor package mounted on at least one side of a board.

7. The semiconductor device of claim 6, wherein the heat sink is attached to a top surface of the semiconductor package.

8. The semiconductor device of claim 1, wherein the semiconductor device includes a semiconductor module having at least one stack package mounted on at least one side of a board.

9. The semiconductor device of claim 8, wherein the heat sink is attached to a top surface of the stack package.

10. A method of separating a heat sink from at least one side of a semiconductor device attached via at least one adhesive, the method comprising:
heating the heat sink, the adhesive, and the semiconductor device; and
separating the heat sink and the semiconductor device such that no residue remains on the semiconductor device.

11. The method of claim 10, wherein the adhesive is a thermally induced adhesive in which an adhesive strength of the thermally induced adhesive decreases when heated.

12. The method of claim 10, wherein the adhesive includes conductive particles.

13. The method of claim 12, wherein the conductive particles include at least one of Ag, Cu or Ni, and ceramic particles.

14. The method of claim 10, wherein the semiconductor device is one of a semiconductor chip, a semiconductor chip package, a semiconductor stack, and a semiconductor stack package.
